(19) United States
(12) Patent Application Publication
(10) Pub. No.: US 2021/0407030 A1
(43) Pub. Date: Dec. 30, 2021

(54) DEVICE FOR SETTING ORDER OF CARGO SHIPMENT

(71) Applicant: TOTAL SOFT BANK LTD., Busan (KR)

(72) Inventor: Hoon LEE, Busan (KR)

(21) Appl. No.: 17/294,869

(22) PCT Filed: Nov. 18, 2019
(86) PCT No.: PCT/KR2019/015756

§ 371 Date: Jun. 8, 2021

(30) Foreign Application Priority Data
Nov. 19, 2018 (KR) 10-2018-0142335

(51) Int. Cl. G06Q 50/28; G06Q 10/06; G06Q 10/04; G06F 30/20

(52) U.S. Cl. CPC G06Q 50/28; G06Q 10/067; G06F 30/20; G06Q 10/06313; G06Q 10/047

(57) ABSTRACT

One embodiment can provide a device for setting the order of a cargo shipment, comprising: a communication unit for receiving, from an external organization, preliminary data related to a ship and cargo; and a control unit for receiving the preliminary data from the communication unit, wherein the control unit generates preliminary cargo shipment order data related to the shipment order of the cargo on the basis of the preliminary data, simulates shipment of the cargo on the ship on the basis of the preliminary cargo shipment order data, re-generates the preliminary cargo shipment order data if the shipment of the cargo is not implemented in the ship as a result of the simulation, and sets the preliminary cargo shipment order data as determined cargo shipment order data if the shipment of the cargo is implemented in the ship as the result of the simulation.

### TECHNICAL FIELD

The present invention relates to a device for setting order of cargo shipment, and more particularly, to a device for setting order of cargo shipment through a feedback process.

### BACKGROUND ART

The order that cargo is loaded on a ship may be varied according to size of loaded cargo and shape of the ship. If the order of cargo shipment is not planned, shipment efficiency of cargo may become relatively low and temporal and financial damages may occur.

According to a conventional method or device for setting order of cargo shipment, the order of cargo shipment may be set according to a feed-forward method. However, if an error occurs in order of cargo shipment, the order of cargo shipment must be reset, but it may lower efficiency.

After the order of cargo shipment is set, measures for stably setting order of cargo shipment by simulating the set order of cargo shipment to give feedback.

### PATENT LITERATURE

### Patent Documents

Patent Document 1: Korean Patent Publication No. 10-2015-0058332

### DISCLOSURE

### Technical Problem

Accordingly, the present invention has been made in an effort to solve the above-mentioned problems occurring in the prior arts, and it is an object of the present invention to provide a device for stably setting order of cargo shipment through a feedback process.

Technical objects to be achieved by the present invention are not limited to the above-described objects and other technical objects that have not been described will be evidently understood by those skilled in the art from the following description.

### Technical Solution

To achieve the above objects, the present invention provides a device for setting order of cargo shipment including: a communication unit for receiving preliminary data related to a ship and cargo from an external organization; and a control unit for receiving the preliminary data from the communication unit, wherein the control unit generates preliminary cargo shipment order data related to shipment order of the cargo on the basis of the preliminary data, simulates shipment of the cargo on the ship on the basis of the preliminary cargo shipment order data, re-generates the preliminary cargo shipment order data if the shipment of the cargo is not implemented in the ship as a result of the simulation, and sets the preliminary cargo shipment order data as determined cargo shipment order data if the shipment of the cargo is implemented in the ship as the result of the simulation.

### Advantageous Effects

The device for setting order of cargo shipment according to the present invention can stably set order of cargo shipment through a feedback process.

The effects of the present invention are not limited to the above-mentioned effect and further effects derivable from the detailed description of invention or claims of the present invention will be clearly understood by those skilled in the art.

### DESCRIPTION OF DRAWINGS

FIGS. 1A-1B are views showing a device for setting order of cargo shipment according to a preferred embodiment of the present invention.

FIGS. 2A-2B are views showing a ship capable of shipping cargo.

FIG. 3 is a view showing contents of a cargo table 200.

FIGS. 4A-4B are views showing a ship 100 on which cargo shipment zones are indicated.

FIG. 5 is a view showing the cargo shipment zones in consideration of a cargo movement route.

FIGS. 6A-6C are views showing subdivided cargo shipment zones having order of priority.

FIG. 7 is a view showing execution of simulation related with cargo shipment.

FIG. 8 is a view showing the ship on which cargo is loaded.

FIGS. 9 to 12 are flow charts showing a “cargo shipping method” according to the preferred embodiment of the present invention.

### MODE FOR INVENTION

Hereinafter, the present invention will be described in detail with reference to the accompanying drawings. However, embodiments of the present invention may be implemented in several different forms and are not limited to the embodiments described herein. In addition, parts irrelevant to description are omitted in the drawings in order to clearly explain embodiments of the present invention. Similar parts are denoted by similar reference numerals throughout this specification.

Throughout this specification, when a part is referred to as being “connected” to another part, this includes “direct connection” and “indirect connection” via an intervening part. Also, when a certain part “includes” a certain component, other components are not excluded unless explicitly described otherwise, and other components may in fact be included.

The terminology used herein is for the purpose of describing particular embodiments only and is not intended to be limiting of the inventive concept. As used herein, the singular forms “a”, “an”, and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

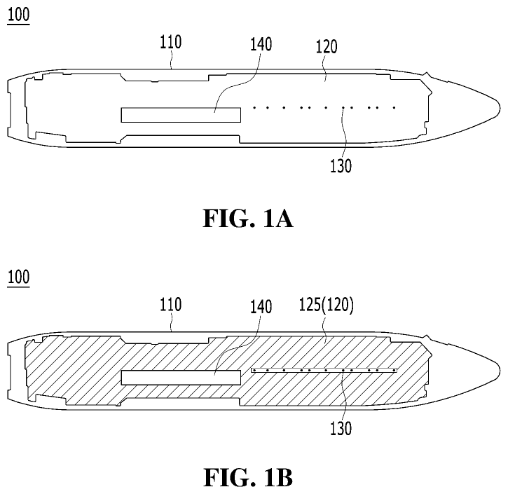

FIGS. 1A-1B are views showing a cargo shipment zone setting system according to a preferred embodiment of the present invention. The cargo shipment zone setting system 10 may be called a “cargo shipment order setting system” or a “cargo shipment order setting device”.

Referring to FIGS. 1A-1B, the cargo shipment zone setting system 10 according to the preferred embodiment of the present invention may be implemented using a server. The server may be implemented using a computer, a laptop, a PCB, or a logic circuit.

The cargo shipment zone setting system 10 includes a control unit 11. The control unit 11 carries out operation or simulation. The control unit 11 carries out preset programs. The control unit 11 may be a “processor”.

The cargo shipment zone setting system 10 includes a communication unit 12. The communication unit 12 communicates with an external device. For instance, the communication unit 12 sends and receives information and/or signals to and from an external organization 20. For instance, the external organization 20 may be an organization which manages cargo movement between a harbor and a ship. The communication unit 12 can send and receive a first signal 51 to and from the external organization 20. For instance, the communication unit 12 receives the first signal 51 from the external organization 20 and transfer it to the control unit 11.

The cargo shipment zone setting system 10 includes an input unit 13. The input unit 13 is connected to the control unit 11. The input unit 13 acquires an input from a user and transfers it to the control unit 11. The input acquired by the input unit 13 includes command information related with controls of the control unit 11.

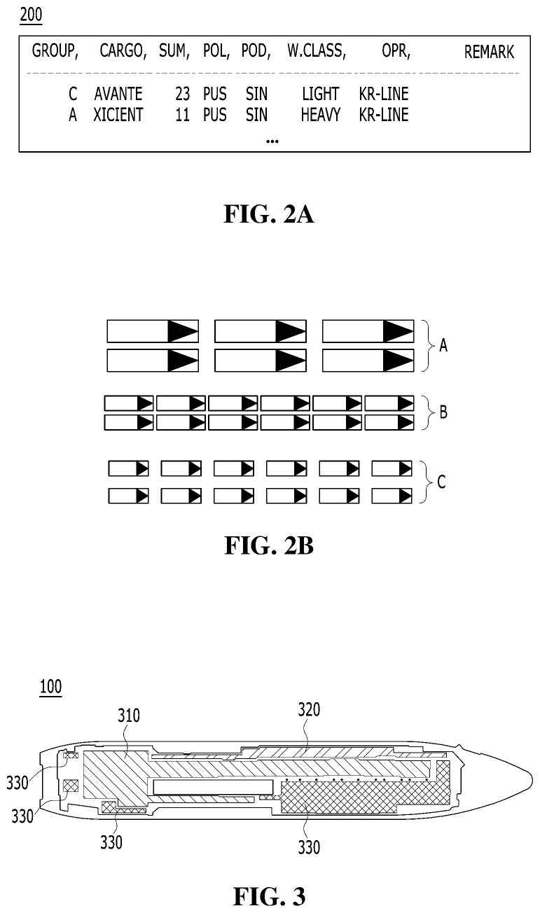

FIGS. 2A-2B are views showing a ship capable of shipping cargo. FIGS. 2A-2B are top views of the ship. FIG. 2A is a top view of a ship 100 for shipping cargo. FIG. 2B shows cargo shippable zones 125 in the ship 100 indicated in FIG. 2A.

Referring to FIG. 2A, the ship 100 includes a hull 110. The hull 110 forms a frame of the ship 100. The hull 110 has a receiving space formed therein. Moreover, the hull 110 has a space for shipment formed at the top thereof.

The ship 100 has a deck 120. The deck 120 forms an upper surface of the ship 100. The deck 120 has a space for receiving cargo. The deck is horizontal. The deck 120 may be divided into several zones.

The ship 100 includes pillars 130. Devices necessary for managing the ship 100 are mounted on the pillars 130. A plurality of the pillars 130 are provided. The pillars 130 are located on the deck 120. The pillars 130 extend upwards from the deck 120.

The ship 100 includes a ramp 140. The ramp 140 is used to move cargo from the deck 120. The ramp 140 is located on the deck 120. The ramp 140 is to load or unload cargo from a port.

Referring to FIG. 2B, the entire zone of the deck 120 is divided into cargo shippable zones 125 and cargo unshippable zones. The cargo shippable zone 125 means a zone on which cargo can be loaded theoretically. Structures located on the deck 120 excludes spaces on which cargo is loaded. For instance, the ramp 140 or the pillars 130 may remove the spaces that cargo is shipped on the deck 120.

The communication unit 12 (refer to FIGS. 1A-1B) acquires structure-related information of the ship 100 from the external organization 20 (refer to FIGS. 1A-1B). For instance, the first signal 51 (refer to FIGS. 1A-1B) calculates the cargo shippable zones 125 on the basis of the structure-related information of the ship 100. The structure-related information of the ship 100 may include preliminary data.

The cargo shippable zone 125 may not mean a shippable zone for all kinds of cargo. For instance, relative bulky cargo cannot be shipped in a narrow space, but small cargo can be shipped in a narrow space. That is, in order to calculate a zone for shipping cargo on the deck 120, the cargo shippable zones 125 and information on actual cargo may be required.

FIG. 3 is a view showing contents of a cargo table 200.

Referring to FIG. 3, the cargo table 200 has a plurality of fields. For instance, a plurality of the fields include group, kind of cargo, sum, pol, pod, weight class, and so on. The communication unit 12 (refer to FIGS. 1A-1B) receives the first signal 51 (refer to FIGS. 1A-1B) containing information on the cargo table 200. The cargo table 200 may be included in the preliminary data.

Referring to FIG. 3(b), cargo of each group may be indicated by different sizes. For instance, an A group cargo (A) which is a large-sized truck is indicated relatively largely. A C group cargo (C) which is a car is indicated relatively small. A B group cargo (B) which is a middle-sized truck is indicated in a medium size. For the convenience of description, it may be assumed that the A group cargo (A), the B group cargo (B), and the C group cargo (C) are shipped on the ship 100 (refer to FIGS. 1A-1B).

The information on the cargo shippable zones 125 and the data including the cargo table 200 is called a “first data”. The control unit 11 (refer to FIGS. 1A-1B) generates the first data based on the structure-related information of the ship 100.

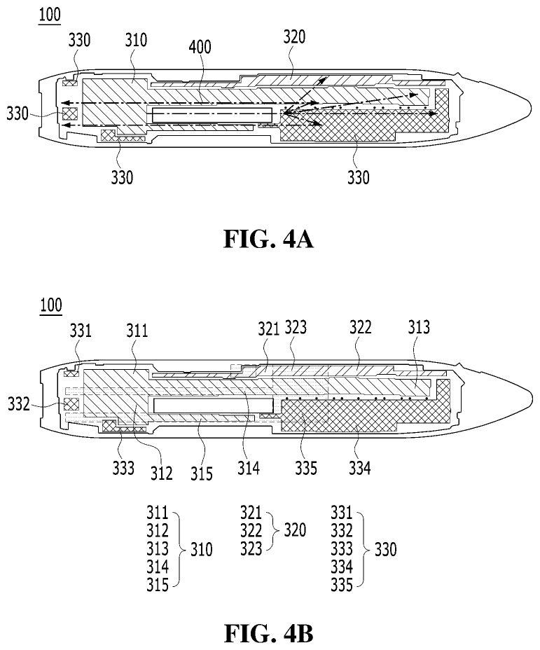

FIGS. 4A-4B are views showing a ship 100 on which cargo shipment zones are indicated.

Referring to FIGS. 4A-4B, the cargo shipment zones 310, 320 and 330 are zones allotted to cargo of each group among the cargo shippable zones 125 (refer to FIGS. 2A-2B) of the ship 100 in consideration of the cargo table 200 (refer to FIG. 3).

For instance, the A zone 310 may mean a zone in which the A group cargo (A) (refer to FIG. 3) is shipped. The B zone 320 may mean a zone in which the B group cargo (B) (refer to FIG. 3) is shipped. The C zone 330 may mean a zone in which the C group cargo (C) (refer to FIG. 3) is shipped.

The data containing the information on the cargo shipment zones 310, 320 and 330 is called a “second data”. The cargo shipment zones 310, 320 and 330 may be set in consideration of order of bulky cargo among the shipped cargo. The control unit 11 (refer to FIG. 1) generates the second data based on the information on the cargo table 200 included in the first signal 51 (refer to FIGS. 1A-1B) and the first data.

For instance, because the A group cargo (A) (refer to FIG. 3) is the large-sized truck which is relatively bulky, The A group cargo (A) (refer to FIG. 3) may be considered preferentially in setting the cargo shipment zones 310, 320 and 330. After that, because the B group cargo (B) is the middle-sized truck which is relatively bulky, the B group cargo (B) (refer to FIG. 3) may be considered suboptimally. After that, the C group cargo (C) (refer to FIG. 3) may be considered finally.

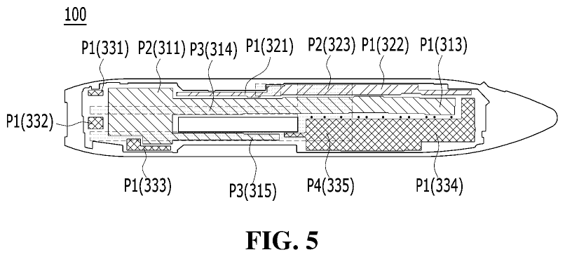

FIG. 5 is a view showing the cargo shipment zones in consideration of a cargo movement route.

Referring to FIG. 5(a), a cargo movement route 400 is indicated. It may be difficult to directly move cargo from a port to a designated location of the ship 100. Therefore, the cargo is moved to a temporary location of the ship 100, and then, is moved to the designated location. For instance, the cargo is moved to the ramp 140 (refer to FIGS. 2A-2B) of the ship 100, and then, is moved to the designated location. Data including information on the cargo movement route 400 in the ship 100 is called a “third data”.

Referring to FIG. 5(b), “subdivided cargo shipment zones” considering the cargo movement route 400 may be indicated. The cargo movement route 400 forms boundary with the cargo shipment zones 310, 320 and 330. The cargo shipment zones 310, 320 and 330 are sorted as the “subdivided cargo shipment zones” by the boundary. Data including information on the “subdivided cargo shipment zones” is called a “fourth data”.

The control unit 11 (refer to FIGS. 1A-1B) generates the third data based on the second data. The control unit 11 (refer to FIGS. 1A-1B) generates the fourth data based on the third data.

If the first cargo is located on the cargo movement route 400, the first cargo may obstruct movement of the second cargo. Therefore, the cargo shipment zones 310, 320 and 330 are subdivided in consideration of the cargo movement route 400, and cargo is shipped depending on the subdivided cargo shipment zones.

For instance, the A zone 310 may be subdivided into a first A zone 311, a second A zone 312, a third A zone 313, a fourth A zone 314, and a fifth A zone 315. For instance, the B zone 320 may be subdivided into a first B zone 321, a second B zone 322, a third B zone 323, a fourth B zone 324, and a fifth B zone 325. For instance, the C zone 330 may be subdivided into a first C zone 331, a second C zone 332, a third C zone 333, a fourth C zone 334, and a fifth C zone 335.

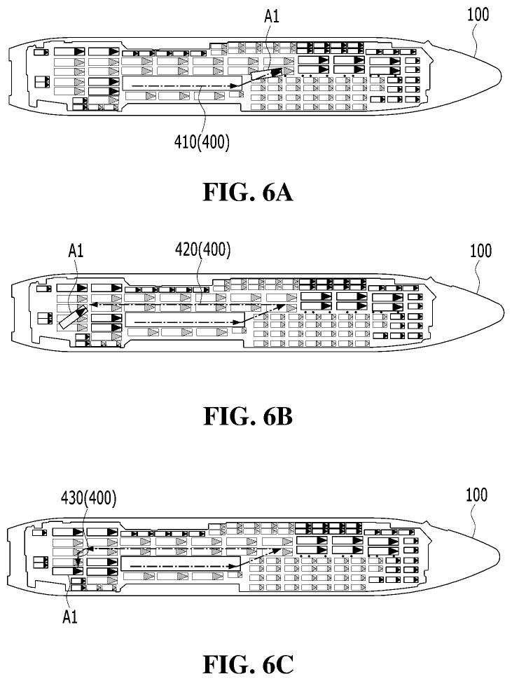

FIGS. 6A-6C are views showing subdivided cargo shipment zones having order of priority.

The “subdivided cargo shipment zones” illustrated in FIG. 5 may be divided into “subdivided cargo shipment zones having order of priority” referring to FIGS. 6A-6C. Data including information on “subdivided cargo shipment zones having order of priority” is called a “fifth data”. The control unit 11 (refer to FIGS. 1A-1B) generates the fifth data based on the fourth data. The fifth data is called “preliminary cargo shipment order data”.

For instance, the “subdivided cargo shipment zones P1, P2, P3 and P4 having order of priority” include a first priority zone P1, a second priority zone P2, a third priority zone P3, and a fourth priority zone P4. The “subdivided cargo shipment zones P1, P2, P3 and P4 having order of priority” mean that order of priority is applied to the subdivided cargo shipment zones 310, 320 and 330 (refer to FIG. 5).

If cargo is shipped in the second to fourth priority zones P2 to P4 before cargo is shipped in the first priority zone P1, it may be difficult to move cargo which must be located in the first priority zone P2. If cargo is shipped in the third and fourth priority zones P3 and P4 before cargo is shipped in the second priority zone P2, it may be difficult to move cargo which must be located in the second priority zone P2. If cargo is shipped in the fourth priority zone P4 before cargo is shipped in the third priority zone P3, it may be difficult to move cargo which must be located in the third priority zone P3.

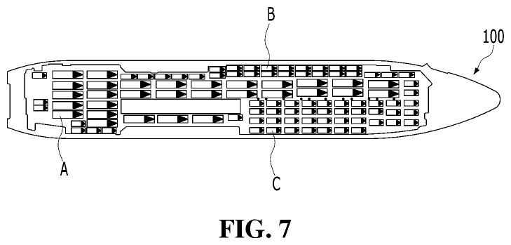

FIG. 7 is a view showing execution of simulation related with cargo shipment.

Referring to FIG. 7(a), the first A cargo A1 can move forwards along a forward movement route 410 after being put on the ramp 140 (refer to FIGS. 1A-1B). Referring to FIG. 7(b), the first A cargo A1 can move backwards along a backward movement route 420. Referring to FIG. 7(c), the first A cargo A1 can rotate along a rotational movement route 430 and is located in position in a proper position.

Referring to FIGS. 6 and 7, a destination of the first A cargo A1 may be the second priority zone P2. Therefore, in movement of the first A cargo A1, the third and fourth priority zones P3 and P4 may be required. Because there is no cargo in the third and fourth priority zones P3 and P4, the first A cargo A1 can be moved to the destination.

Such simulation may be executed by the control unit 11 (refer to FIGS. 1A-1B).

If there is a lack of a space for shipment as a result of the simulation, the control unit 11 (refer to FIGS. 1A-1B) regenerates the second data, and renews from the third data to the fifth data based on the second data.

If there is a collision probability on the cargo movement route as a result of the simulation, the control unit 11 (refer to FIGS. 1A-1B) regenerates the third data, and renews from the fourth data to the fifth data based on the third data.

If the cargo shipment zones are not effective as a result of the simulation, the control unit 11 (refer to FIGS. 1A-1B) regenerates the fourth data, and renews the fifth data based on the fourth data.

If the cargo does not reach the destination as a result of the simulation, the control unit 11 (refer to FIGS. 1A-1B) regenerates the fifth data.

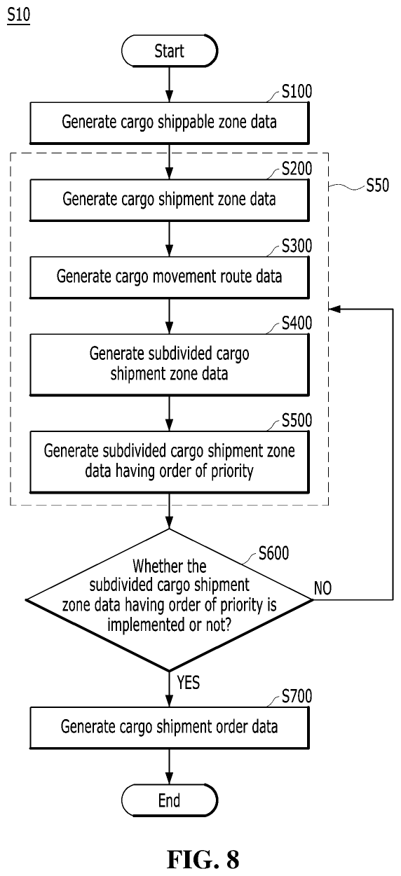

FIG. 8 is a view showing the ship on which cargo is loaded.

FIG. 8 illustrates that all kinds of cargo are shipped on the ship 100 through the simulation illustrated in FIG. 7. If it is verified that the fifth data is effective through the simulation, the control unit 11 (refer to FIGS. 1A-1B) can set the fifth data as “cargo shipment order data”. The cargo shipment order data includes information on “cargo shipment order”. The cargo shipment order data may be called “determined cargo shipment order data”.

The control unit 11 (refer to FIGS. 1A-1B) provides the cargo shipment order data to the communication unit 12 (refer to FIGS. 1A-1B). The communication unit 12 (refer to FIGS. 1A-1B) transfers the cargo shipment order data to the external organization 20 (refer to FIGS. 1A-1B). In this instance, the first signal 51 (refer to FIGS. 1A-1B) includes the cargo shipment order data.

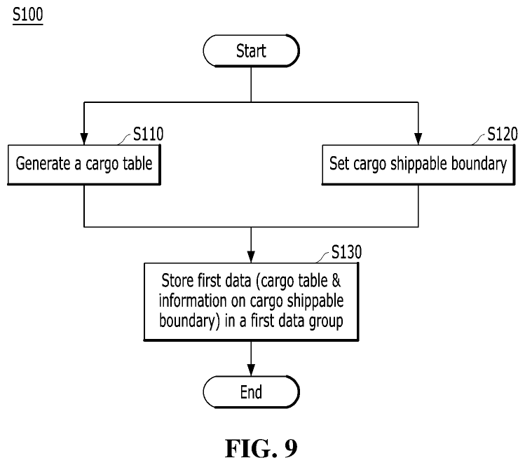

FIGS. 9 to 12 are flow charts showing a “cargo shipment method” according to the preferred embodiment of the present invention.

The cargo shipment method S10 according to the preferred embodiment of the present invention includes a step (S100) of generating cargo shippable zone data. The step (S100) may be called a first step (S100) and is carried out by the control unit 11 (refer to FIGS. 1A-1B). The control unit 11 (refer to FIGS. 1A-1B) acquires the structure-related information of the ship 100 (refer to FIGS. 2A-2B) and the cargo table 200 (refer to FIG. 3) from the external organization 200 (refer to FIG. 3). The control unit 11 (refer to FIGS. 1A-1B) generates cargo shippable zone data on the basis of the structure-related information of the ship 100 (refer to FIGS. 2A-2B) and the cargo table 200 (refer to FIG. 3). The cargo shippable zone data may be called the first data.

The cargo shipment method (S10) according to the preferred embodiment of the present invention includes a planning step (S50). The control unit 11 (refer to FIGS. 1A-1B) carries out the planning step (S50). In the planning step (S50), the control unit 11 (refer to FIGS. 1A-1B) can set order of cargo shipment based on the first data. The planning step (S50) includes second to fifth steps (S200, S300, S400 and S500) which will be described later.

The cargo shipment method (S10) according to the preferred embodiment of the present invention includes a step (S200) of generating cargo shipment zone data. The step (S200) of generating cargo shipment zone data is included in the planning step (S50). The step (S200) of generating cargo shipment zone data is carried out by the control unit 11 (refer to FIGS. 1A-1B). The cargo shipment zone data may be called the second data. In the step (S200), the control unit 11 (refer to FIGS. 1A-1B) generates the second data based on the first data. The step (S200) may be called a second step (S200). The second data generated in the step (S200) may correspond to the cargo shipment zones 310, 320 and 33 illustrated in FIGS. 4A-4B.

The cargo shipment method (S10) according to the preferred embodiment of the present invention includes a step (S300) of generating cargo movement route data. The step (S300) of generating cargo movement route data is included in the planning step (S50). The step (S300) is carried out by the control unit 11 (refer to FIGS. 1A-1B). The cargo movement route data may be called the third data. In the step (S300), the control unit 11 (refer to FIGS. 1A-1B) generates the third data based on the second data. The step (S300) may be called a third step (S300). The third data generated in the step (S300) may correspond to the cargo movement route 400 illustrated in FIG. 5(a).

The cargo shipment method (S10) according to the preferred embodiment of the present invention includes a step (S400) of generating subdivided cargo shipment zone data. The step (S400) of generating subdivided cargo shipment zone data is included in the planning step (S50). The step (S400) is carried out by the control unit 11 (refer to FIGS. 1A-1B). The subdivided cargo shipment zone data may be called the fourth data. In the step (S400), the control unit 11 (refer to FIGS. 1A-1B) generates the fourth data based on the third data. The step (S400) may be called a fourth step (S400). The fourth data generated in the step (S400) may correspond to the subdivided cargo shipment zones 311, 312, 313, 314, 315, 321, 322, 323, 331, 332, 333, 334 and 335 illustrated in FIG. 5(b).

The cargo shipment method (S10) according to the preferred embodiment of the present invention includes a step (S500) of generating subdivided cargo shipment zone data having order of priority. The step (S500) of generating subdivided cargo shipment zone data having order of priority is included in the planning step (S50). The step (S500) is carried out by the control unit 11 (refer to FIGS. 1A-1B). The subdivided cargo shipment zone data having order of priority may be called the fifth data. In the step (S500), the control unit 11 (refer to FIGS. 1A-1B) generates the fifth data based on the fourth data. The step (S500) may be called a fifth step (S500). The fifth data generated in the step (S500) may correspond to the subdivided cargo shipment zones P1, P2, P3 and P4 having order of priority illustrated in FIGS. 6A-6C.

The cargo shipment method (S10) according to the preferred embodiment of the present invention includes a step (S600) of judging implementability of the subdivided cargo shipment zone data having order of priority. The step (S600) is carried out by the control unit 11 (refer to FIGS. 1A-1B). The control unit 11 (refer to FIGS. 1A-1B) verifies implementability or realizability of the fifth data in the step (S600). For instance, in the step (S600), the control unit 11 (refer to FIGS. 1A-1B) can verify the fifth data by simulation. The step (S600) may be called a verification step (S600). In the step (S600), if the control unit 11 (refer to FIGS. 1A-1B) judges that the fifth data is not implementable, the control unit 11 carries out the planning step (S50). The step (S600) may be called a sixth step (S600). In the step (S600), the control unit 11 (refer to FIGS. 1A-1B) carries out simulation based on the fifth data in order to know whether cargo can reach a designated location of the ship.

The cargo shipment method (S10) according to the preferred embodiment of the present invention includes a step (S700) of generating cargo shipment order data. The step (S700) may be called a seventh step (S700). In the step (S600), if the control unit 11 (refer to FIGS. 1A-1B) judges that the fifth data is implementable, the control unit 11 carries out the step (S700). In the step (S700), the control unit 11 (refer to FIGS. 1A-1B) may set the fifth data as the cargo shipment order data. FIG. 8 illustrates cargoes A, B and C (refer to FIG. 8) shipped on the ship 100 (refer to 100) are arranged by the cargo shipment order data generated in the step (S700).

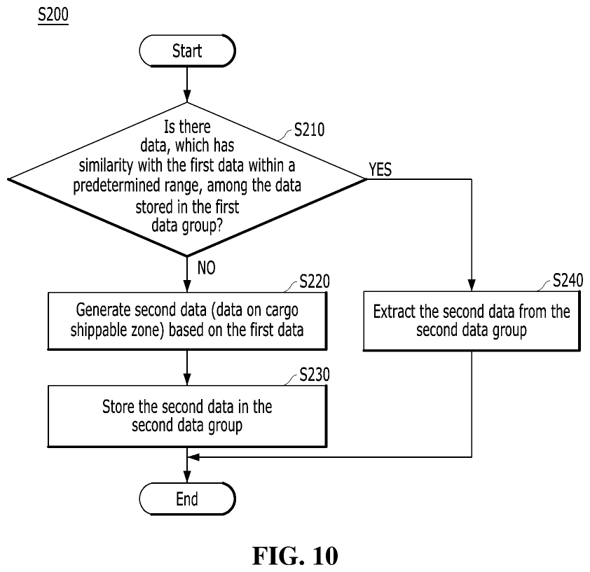

Referring to FIG. 10, the first step (S100) includes a step (S110) of generating a cargo table. The step (S110) is carried out by the control unit 11 (refer to FIGS. 1A-1B). In the step (S110), the control unit 11 (refer to FIGS. 1A-1B) acquires information on the cargo, which will be shipped on the ship 100 (refer to FIGS. 2A-2B), from the external organization 20 (refer to FIGS. 1A-1B), and generates the cargo table 200 (refer to FIG. 3) based on the information on the cargo. Moreover, in the step (S110), the control unit 11 (refer to FIGS. 1A-1B) acquires the cargo table 200 (refer to FIG. 3) from the external organization 20 (refer to FIGS. 1A-1B).

The first step (S100) includes a step (S120) of setting a cargo shipment boundary. Information on the cargo shipment boundary may correspond to the cargo shippable zones 125 (refer to FIGS. 2A-2B). In the step (S120), the control unit 11 (refer to FIGS. 1A-1B) acquires the structure-related information of the ship 100 (refer to FIGS. 2A-2B) from the external organization 20 (refer to FIGS. 1A-1B), and sets the cargo shippable zones 125 (refer to FIGS. 2A-2B) based on the structure-related information of the ship.

The first step (S100) includes a step (S130) of storing the first data in a first data group. The first data includes information on the cargo table 200 (refer to FIG. 3) and the cargo shippable zones 125 (refer to FIGS. 2A-2B). The first data group includes the first data by a plurality of examples. The step (S130) is carried out by the control unit 11 (refer to FIGS. 1A-1B).

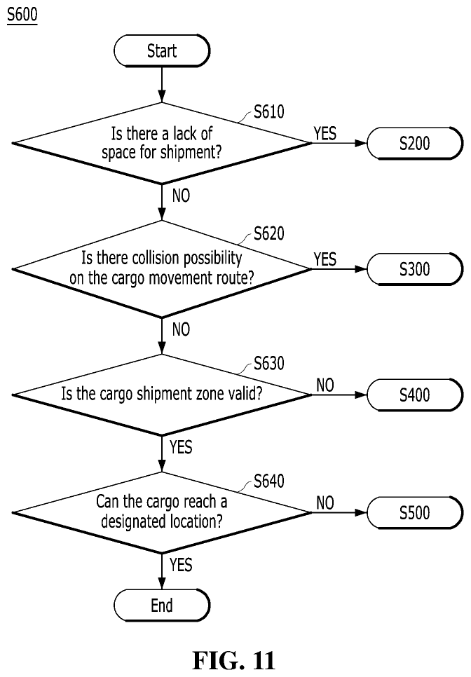

Referring to FIG. 11, the second step (S200) includes a step (S210) of judging whether there is data, which has similarity with the first data within a predetermined range, among the data stored in the first data group. In the step (S210), the control unit 11 (refer to FIGS. 1A-1B) judges whether there is data identical or similar to the first data within a predetermined range, among data stored in the first data group.

The second step (S200) includes a step (S220) of generating second data based on the first data. If it is judged that there is no data identical or similar to the first data within a predetermined range, among data stored in the first data group, in the step (S220), the control unit 11 (refer to FIGS. 1A-1B) generates the second data based on the first data.

The second step (S200) includes a step (S230) of storing the second data in the second data group. The second data group is linked with the first data group. For instance, the first data and the second data according to a plurality of the examples may be linked together by examples. The step (S230) is carried out by the control unit 11 (refer to FIGS. 1A-1B).

The second step (S200) includes a step (S240) of extracting the second data from the second data group. The step (S240) is carried out by the control unit 11 (refer to FIGS. 1A-1B). If it is judged that there is data identical or similar to the first data within a predetermined range, among data stored in the first data group, in the step (S240), the control unit 11 (refer to FIGS. 1A-1B) extracts the second data linked with the similar first data from the second data group.

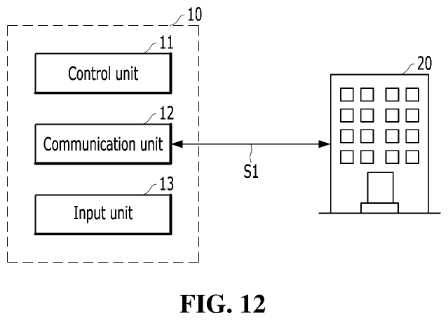

Referring to FIG. 12, the sixth step (S600) includes a step (S610) of judging whether there is a lack of a space for shipment. The step (S610) is carried out by the control unit 11 (refer to FIGS. 1A-1B). The control unit 11 (refer to FIGS. 1A-1B) verifies the fifth data. If it is judged that there is a lack of a space for shipment, the control unit 11 carries out the second step (S200).

The sixth step (S600) includes a step (S620) of judging whether there is collision possibility on the cargo movement route. If it is judged that the space for shipment is enough, the control unit 11 (refer to FIGS. 1A-1B) carries out the step (S620). The control unit 11 (refer to FIGS. 1A-1B) verifies the fifth data. If it is judged that there is collision possibility on the cargo movement route, the control unit 11 carries out the third step (S300).

The sixth step (S600) includes a step (S630) of judging whether the cargo shipment zones are valid. If it is judged that there is no collision possibility on the cargo movement route, the control unit 11 (refer to FIGS. 1A-1B) carries out the step (S630). The control unit 11 (refer to FIGS. 1A-1B) verifies the fifth data. If it is judged that the cargo shipment zones are not valid, the control unit 11 carries out the fourth step (S400).

The sixth step (S600) includes a step (S640) of judging whether the cargo can reach the designated location. If it is judged that the cargo shipment zones are valid, the control unit 11 (refer to FIGS. 1A-1B) carries out the step (S640). After verification of the fifth data, if it is judged that the cargo cannot reach the designated location, the control unit 11 (refer to FIGS. 1A-1B) carries out the fifth step (S500). The control unit 11 (refer to FIGS. 1A-1B) verifies the fifth data. If it is judged that the cargo can reach the designated location, the control unit 11 carries out the seventh step (S700) (refer to FIG. 9).

The above description of the present disclosure is just for illustration, and a person skilled in the art will understand that the present disclosure can be easily modified in different ways without changing essential techniques or features of the present disclosure. Therefore, the above embodiments should be understood as being descriptive, not limitative. For example, any component described as having an integrated form may be implemented in a distributed form, and any component described as having a distributed form may also be implemented in an integrated form.

The scope of the present disclosure is defined by the appended claims, rather than the above description, and ail changes or modifications derived from the meaning, scope and equivalents of the appended claims should be interpreted as falling within the scope of the present disclosure.

<Explanation of essential reference numerals in drawings>

| | |
|---|---|
| 10: | cargo shipment zone setting system |
| 11: | control unit |
| 12: | communication unit |
| 13: | input unit |
| 100: | ship |
| 110: | hull |
| 120: | deck |
| 125: | cargo shippable zone |
| 130: | pillar |
| 200: | cargo table |
| 310: | A zone |
| 320: | B zone |
| 330: | C zone |
| 400: | movement route |
| P1: | first priority zone |
| P2: | second priority zone |
| P3: | third priority zone |
| P4: | fourth priority zone |

1. A device for setting order of cargo shipment comprising:
a communication unit for receiving preliminary data related to a ship and cargo from external organization; and
a control unit for receiving the preliminary, data from the communication unit,
wherein the control unit generates preliminary cargo shipment order data related to shipment order of the cargo on the basis of the preliminary data, simulates shipment of the cargo on the ship on the basis of the preliminary cargo shipment order data, re-generates the preliminary cargo shipment order data if the shipment of the cargo is not implemented in the ship as a result of the simulation, and sets the preliminary cargo shipment order data as determined cargo shipment order data if the shipment of the cargo is implemented in the ship as the result of the simulation.

2. The device for setting order of cargo shipment according to claim 1, wherein the preliminary data includes:
structure-related information of the ship; and
information on the cargo to be shipped in the ship.

3. The device for setting order of cargo shipment according to claim 2, wherein the control unit calculates cargo shippable zones in the ship on the basis of the preliminary data, and generates a first data including information on the cargo shippable zones and information on the cargo.

4. The device for setting order of cargo shipment according to claim 3, wherein the control unit calculates cargo shipment zones divided from the cargo shippable zones according to kinds of the cargo on the basis of the first data, and generates a second data including information on the cargo shipment zones.

5. The device for setting order of cargo shipment according to claim 4, wherein the control unit calculates a cargo movement route in the ship on the basis of the second data, and generates a third data including information on the cargo movement route.

6. The device for setting order of cargo shipment according to claim 5, wherein the control unit calculates subdivided cargo shipment zones subdivided from the cargo shipment zones by the cargo movement route on the basis of the third data, and generates a fourth data including information on the subdivided cargo shipment zones.

7. The device for setting order of cargo shipment according to claim 6, wherein the control unit calculates subdivided cargo shipment zones subdivided from the cargo shipment zones by the cargo movement route on the basis of the third data, and generates a fourth data including information on the subdivided cargo shipment zones.

8. The device for setting order of cargo shipment according to claim 7, wherein the control unit carries out simulation, and renews the second data if judging that there is a lack of a space for shipment in the ship.

9. The device for setting order of cargo shipment according to claim 8, wherein the control unit carries out simulation, and renews the third data if judging that there is collision possibility of the cargo on the cargo movement route.

10. The device for setting order of cargo shipment according to claim 9, wherein the control unit carries out simulation, and renews the fourth data if judging that the cargo shipment zone is not valid.

11. The device for setting order of cargo shipment according to claim 10, wherein the control unit carries out simulation, and renews the fifth data if judging that the cargo does not reach a designated location.

12. The device for setting order of cargo shipment according to claim 1, wherein the communication unit sends the cargo shipment order data to the external organization.
